(19) United States
(12) Patent Application Publication
(10) Pub. No.: US 2006/0007025 A1
(43) Pub. Date: Jan. 12, 2006

(54) Device and method for encoding data, and a device and method for decoding data

(76) Inventor: Manish Sharma, Sunnyvale, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/888,476

(22) Filed: Jul. 8, 2004

(51) Int. Cl. H03M 7/00

(52) U.S. Cl. 341/50

(57) ABSTRACT

In an embodiment of the present invention there is a device for encoding data. The device includes a data input for receiving an input data stream that includes a plurality of distinct logical values. The input data stream is such that any one of the logical values has substantially the same probability of occurring as any other of the logical values. The device also includes a processor for obtaining an output data stream based on the input data stream. The output data stream is such that a first of the logical values has a lower probability of occurring than a second of the logical values. The device further includes a data output for outputting the output data stream.

### FIELD OF THE INVENTION

The present invention relates generally to detection mechanisms and more particularly to a device and method for encoding data and a device and method for decoding data.

### BACKGROUND OF THE INVENTION

Detection mechanisms or schemes are used to detect the different logical values in data. For instance, in binary data the logical values include a “0” and a “1”. Where the data is binary, for example, the average time T_{avg} it takes a detection mechanism to detect the logical values is approximately: T_{avg}=P(0)*T(0)+P(1)*T(1), where P(0) and P(1) are the probability of a “0” and “1” occurring in the data respectively, while T(0) and T(1) is the time it takes the detection mechanism to detect a “0” and a “1” respectively.

Detection mechanisms are generally geared toward detecting the different logical values equally. That is, the mechanisms assume that over a period of time the logical values in the data have an equal probability of occurring. Thus, in the previous example of binary data P(0) and P(1) would each equal approximately 0.5.

Detection mechanisms generally take about the same amount of time to detect the logical values. That is, where the data is binary T(0) and T(1) are approximately equal. However, there are situations where detection mechanisms require more time to detect a particular logical value than other logical values. An example of one such situation is in the detection of logical values in a spin quantum computer. It has been found that the asymmetry in the detection times can be very large for spin quantum computers—as high as an order of magnitude in some cases.

For detection mechanisms that have an asymmetric detection time, the average time T_{avg} it takes the detection mechanism to detect the logical values can be reduced by transforming (encoding) the data.

### SUMMARY OF THE INVENTION

In an embodiment of the present invention there is a device for encoding data. The device includes a data input for receiving an input data stream that includes a plurality of distinct logical values. The input data stream is such that any one of the logical values has substantially the same probability of occurring as any other of the logical values. The device also includes a processor for obtaining an output data stream based on the input data stream. The output data stream is such that a first of the logical values has a lower probability of occurring than a second of the logical values. The device further includes a data output operable to output the output data stream.

### BRIEF DESCRIPTION OF THE DRAWINGS

The present invention will be more fully understood from the following description of specific embodiments. The description is provided with reference to the accompanying drawings.

FIG. 1 is a block diagram of a system that includes an encoder and a decoder in accordance with an embodiment of the present invention;

FIG. 2 is a flow chart of the various steps performed by the encoder shown in FIG. 1 in accordance with an embodiment of the present invention; and

FIG. 3 is a flow chart of the various steps performed by the decoder shown in FIG. 1 in accordance with an embodiment of the present invention.

### DETAILED DESCRIPTION

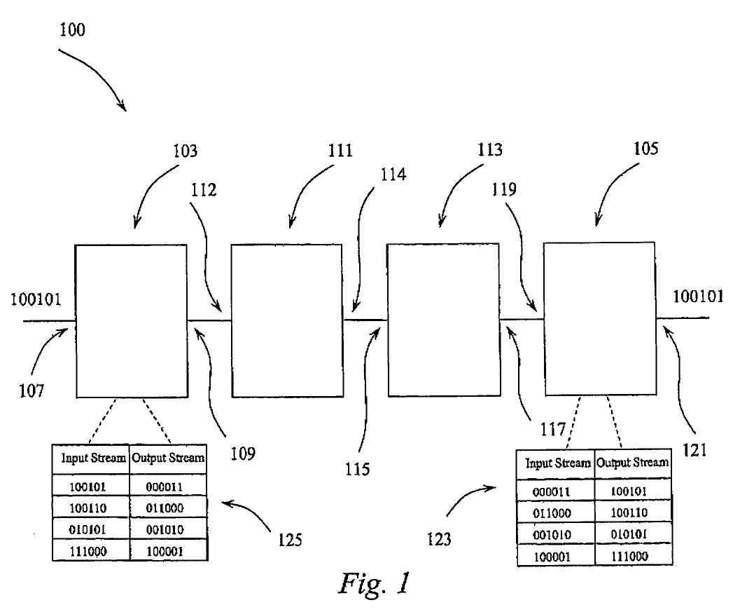

FIG. 1 provides a block diagram of a system 100 that includes a data encoder 103 and a data decoder 105 in accordance with an embodiment. The encoder 103 is in the form of a dedicated integrated circuit. However, it is envisaged that in an alternative embodiment the encoder 103 could be a microprocessor running software. The encoder 103 has an input 107 and an output 109. Generally speaking, the encoder 103 is operable to transform (encode) an input data stream into an output data stream. The output 109 of the encoder 103 is connected to an input 112 of a spin quantum computer 111. The connection enables the output data stream to be transferred from the output 109 to the spin quantum computer 111, where the output data stream is used to direct the spin of electrons in the quantum computer 111.

As persons skilled in the art will appreciate, a spin quantum computer is a device which stores information in quantum mechanical two-level systems (“qubits’) and exploits fundamental quantum mechanical phenomena to vastly improve computational power. The typical elements of a silicon based spin quantum computer includes an array of spin-½ phosphorus nuclei embedded in silicon and a series of surface gate electrodes. The spins of the phosphorus nuclei, which constitute the qubits, will be addressed using a static electric field and manipulated using NMR techniques. Single spin interactions are achieved by a change in a voltage on a metallic gate electrode positioned above each nucleus. Spin-flips are then carried out by a pulse of RF field tuned to the appropriate Stark-shifted resonance frequency. The electron-mediated interaction between two nuclear spins can be turned on and off by applying a voltage to the electrode placed between them (the “J” gate). Conditional spin flips can then be achieved again using the RF field.

The system 100 also includes a detection mechanism 113, which has an input 115 and an output 117. The input 115 is for receiving information on the direction of the spin of electrons in the quantum computer 111, whilst the output 117 is for outputting a binary data stream. The detection mechanism 113 is in the form of a dedicated integrated circuit. However, it is envisaged that the detection mechanism 113 could be a microprocessor running software in an alternative embodiment. The detection mechanism 113 examines the electron spin direction information received on its input 115 and use this information to create the binary data stream which it places on its output 117. The binary data stream that the detection mechanism 113 places on its output 117 corresponds to the data stream fed into the spin quantum computer 111 from the encoder 103.

The detection mechanism 113 has an average detection time T_{avg} for detecting logical values in the information that it receives from the spin quantum computer 111. The average detection time T_{avg} is equal to P(0)*T(0)+P(1)*T(1), where P(0) and P(1) are respectively the probabilities of a “0” and “1” occurring in the information received on input 115, while T(0) and T(1) is the time it takes the detection mechanism 113 to respectively detect a “0” and a “1” in the information received on the input 115.

Because of the nature of the information which the detection mechanism 113 receives on input 115 from the spin quantum computer 111, the detection mechanism 113 has an asymmetric detection time for detecting a “0” and a “1”. More specifically, the detection mechanism 113 takes longer to detect a “1” than it does to detect a “0”. As an example, assume that it takes the detection mechanism 113 0.5 ms to detect a “0” and 1 ms to detect a “1”, then the average detection time T_{avg} is approximately equal to P(0)*0.5+P(1)*1. Furthermore, assume in this example that the probably of receiving a “0” is 0.7 and the probability of receiving a “1” is 0.3. In this example T_{avg} would be 0.7*0.5+0.3*1, which is 0.65 ms.

If, however, the input data stream received by the device 103 on input 107 was fed into the spin quantum computer 111, rather than the output data stream created by the device 103, the average detection time of the detection mechanism 113 would be 0.5*0.5+0.5*1, which is 0.75 ms. What the previous example shows is that the average detection time of the detection mechanism 113 can be reduced by transforming the input data stream (received by the device 113) such that the probably of encountering a “1” is lower than the probability of encountering an “0”.

To transform the binary data stream from the output 117 of the detection mechanism 113, the system 100 includes a decoder 105. The decoder 105 has an input 119 coupled to the output 117 of the detection mechanism 113, and an output 121. In an embodiment, the decoder 105 includes a state table that contains a mapping between binary data streams and output data streams. Using the binary data stream, the decoder 105 ‘looks-up’ the state table to obtain the output data stream in the state table.

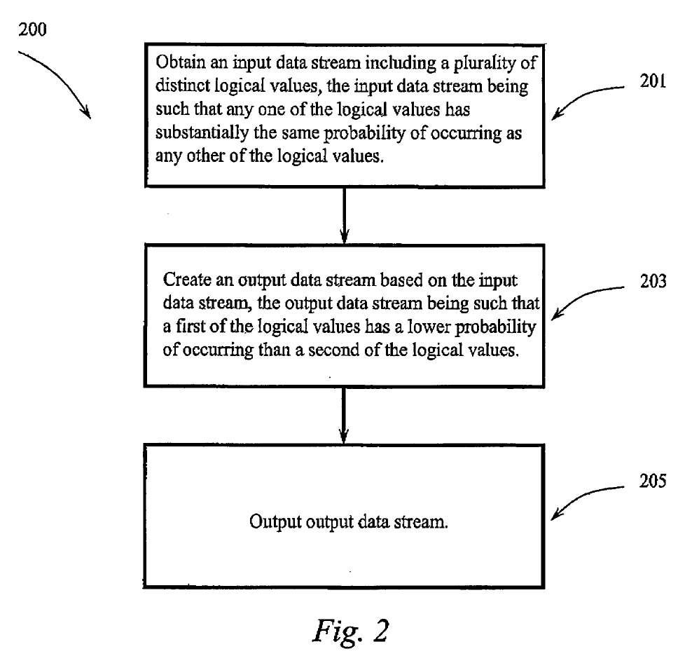

A method 200 of encoding the input data stream in accordance with an embodiment is set out in the flow chart shown in FIG. 2. An initial step 201 includes obtaining the input data stream from the input 107. It is noted that the input data stream is binary and the probability of logical values “0” and “1” occurring over a period of time is approximately equal. That is P(0) and P(1) are both approximately equal to 0.5. Once the input data stream has been obtained, a next step 203 includes creating an output data stream based on the obtained input data stream. It is noted that unlike the input data stream, the output data stream is such that the probability of a “1” occurring over a period of time is lower than the probability of a “0” occurring. In other words, P(1)<P(0). This effectively results in the output data stream having more occurrences of “0” than “1”. In order to transform the input data stream into the output data stream, the encoder 103 includes a state table that contains a mapping between input data streams and output data streams. Using the input data stream the encoder 103 ‘looks-up’ the state table to obtain the output data stream. Once the output data stream has been obtained, a third step 205 includes placing the output data stream onto the output 109.

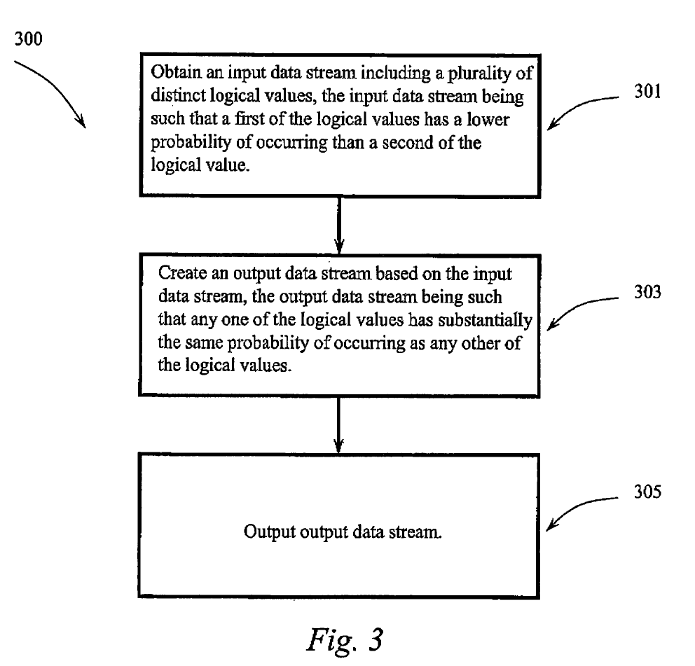

A method 300 in accordance with an embodiment for transforming the binary data stream is set out in the flow chart shown in FIG. 3. The first step 301 includes obtaining the binary data stream, output by the detection mechanism 113, from the input 117. As mentioned previously, the binary data stream output by the detection mechanism 113 is such that the probability of a “1” occurring is lower than the probability of a “0” occurring. A next step 303 includes creating an output data stream based on the binary data stream obtained during step 301.

It is noted that unlike the binary data stream obtained in step 301, the logical values in the output data stream created during step 303 have an equal probability of occurring. A final step 305 includes outputting the data stream for further processing. As mentioned previously, the output data stream created by the decoder 105 corresponds to the input data stream obtained by the encoder 103 during step 301.

In accordance with an embodiment of the present invention, there is provided software which, when run on a computing device, enables the computing device to carry out the method 200 of encoding the input data stream and/or the method 300 of transforming the binary data stream. It is envisaged that the software can be developed using different languages ranging from assembly language to high level programming languages. In an embodiment, the software is distributed on a computer readable medium (for example, a CD-ROM). In an alternative embodiment, the software is distributed via the Internet.

It will be appreciated by those skilled in the art that whilst the preceding description refers to a spin quantum computer, the present invention has application to other systems that may result in the detection mechanism 113 having different times detection times for logical values. Furthermore, it will also be appreciated that the present application can be readily applied to data that has more than two logical values.

What is claimed is:

1. A device for encoding data, the device comprising:
a data input for receiving an input data stream that comprises a plurality of distinct logical values, the input data stream being such that any one of the logical values has substantially the same probability of occurring as any other of the logical values;
a processor for obtaining an output data stream based on the input data stream, the output data stream being such that a first of the logical values has a lower probability of occurring than a second of the logical values; and
a data output operable to output the output data stream.

2. The device as claimed in claim 1, wherein the first of the logical values is such that it takes a detection mechanism more time to detect than the second of the logical values when the data is obtained from a system.

3. The device as claimed in claim 2, wherein the system comprises a spin quantum computer.

4. The device as claimed in claim 1, wherein the distinct logical values are binary.

5. A device for decoding data, the device comprising:
a data input for receiving an input data stream that comprises a plurality of distinct logical values, the input data stream being such that a first of the logical values has a lower probability of occurring than a second of the logical values;
a processor for obtaining an output data stream based in the input data stream, the output data stream being such that any one of the logical values has substantially the same probability of occurring as any other of the logical values; and
a data output operable to output the output data stream.

6. The device as claimed in claim 5, wherein the first of the logical values is such that it takes a detection mechanism more time to detect than the second of the logical values when the data is obtained from a system.

7. The device as claimed in claim 6, wherein the system comprises a spin quantum computer.

8. The device as claimed in claim 5, wherein the distinct logical values are binary.

9. A method of encoding data, the method comprising the steps of:
receiving an input data stream that comprises a plurality of distinct logical values, the input data stream being such that any one of the logical values has substantially the same probability of occurring as any other of the logical values;
obtaining an output data stream based on the input data stream, the output data stream being such that a first of the logical values has a lower probability of occurring than a second of the logical values; and
outputting the output data stream.

10. The method as claimed in claim 9, wherein the first of the logical values is such that it takes a detection mechanism more time to detect than the second of the logical values when the data is obtained from a system.

11. The method as claimed in claim 10, wherein the system comprises a spin quantum computer.

12. The method as claimed in claim 9, wherein the distinct logical values are binary.

13. A method of decoding data, the method comprising the steps of:
receiving an input data stream that comprises a plurality of distinct logical values, the input data stream being such that a first of the logical values has a lower probability of occurring than a second of the logical values;
obtaining an output data stream based in the input data stream, the output data stream being such that any one of the logical values has substantially the same probability of occurring as any other of the logical values; and
outputting the output data stream.

14. The method as claimed in claim 13, wherein the first of the logical values is such that it takes a detection mechanism more time to detect than the second of the logical values when the data is obtained from a system.

15. The method as claimed in claim 14, wherein the system comprises a spin quantum computer.

16. The method as claimed in claim 13, wherein the distinct logical values are binary.

17. A computer program product for encoding data, the computer program product comprising a computer readable medium having computer readable program means for causing a computer to perform the steps of:
receiving an input data stream that comprises a plurality of distinct logical values, the input data stream being such that any one of the logical values has substantially the same probability of occurring as any other of the logical values;
obtaining an output data stream based on the input data stream, the output data stream being such that a first of the logical values has a lower probability of occurring than a second of the logical values; and
outputting the output data stream.

18. A computer program product for decoding data, the computer program product comprising a computer readable medium having computer readable program means for causing a computer to perform the steps of:
receiving an input data stream that comprises a plurality of distinct logical values, the input data stream being such that a first of the logical values has a lower probability of occurring than a second of the logical values;
obtaining an output data stream based in the input data stream, the output data stream being such that any one of the logical values has substantially the same probability of occurring as any other of the logical values; and
outputting the output data stream.
